(19) United States
(12) Patent Application Publication
(10) Pub. No.: US 2013/0154455 A1
(43) Pub. Date: Jun. 20, 2013

(54) MACHINE CASE AND THE PROCESSING METHOD THEREOF

(71) Applicant: Chi-Cheng Hsiao, Taipei City (TW)

(72) Inventor: Chi-Cheng Hsiao, Taipei City (TW)

(73) Assignee: INVENTEC CORPORATION, Taipei City (TW)

(21) Appl. No.: 13/427,053

(22) Filed: Mar. 22, 2012

(30) Foreign Application Priority Data
Dec. 20, 2011 (TW) 100147422

(51) Int. Cl. H05K 5/02; B21D 22/00; B23P 17/00

(52) U.S. Cl. 312/223.2; 29/407.09; 72/379.2

(57) ABSTRACT

A machine case for accommodating at least one electronic device is provided. The machine case includes a top plate and a bottom plate. The bottom plate has a smooth arc surface, the smooth arc surface has a vertex, and a distance between the vertex of the smooth arc surface and the top plate is less than a distance between any other part of the smooth arc surface and the top plate. The smooth arc surface protruding towards the top plate is formed on the bottom plate of the machine case in advance, so that when an electronic device is placed on the bottom plate, the smooth arc surface becomes flat. A processing method of a machine case is further provided. The smooth arc surface is formed according to the deformation of the bottom plate when an electronic device is placed on the bottom plate.

### CROSS-REFERENCE TO RELATED APPLICATION

This application claims the priority benefit of Taiwan application serial no. 100147422, filed on Dec. 20, 2011. The entirety of the above-mentioned patent application is hereby incorporated by reference herein and made a part of this specification.

### BACKGROUND OF THE INVENTION

1. Field of the Invention

The present invention generally relates to a machine case, in particular, to a machine case for accommodating at least one electronic device.

2. Description of Related Art

A server is a core computer in a network system for serving computers, can provide functions of disk and printing services for network users, and at the same time, can be used by user terminals to share resources in the network environment with one another.

Generally, a workstation usually uses a plurality of servers to process a large amount of data, and the servers are placed in a server cabinet. Some of the commercially available server cabinets have several brackets arranged vertically, and generally, the brackets merely support two sides of a bottom plate of a machine case, and the other parts of the bottom plate are suspended, which is beneficial for heat dissipation of servers.

FIG. 1 is a schematic front view of conventional servers placed in a server cabinet 20. Referring to FIG. 1, a conventional server 10 includes a machine case 12 and a plurality of electronic devices 14. The machine case 12 has a bottom plate 12a, the electronic device 14 is located in the machine case 12 and is placed on a bottom plate 12a. As the bottom plate 12a of the machine case 12 bears the weight of the electronic device 14, and most of the bottom plate 12a is suspended when the server 10 is placed in the server cabinet 20, the bottom plate 12a is depressed downwards and deforms due to the excessively heavy weight of the electronic device 14.

In the server cabinet, as the bottom plate of the machine case changes from a flat surface into an arc surface, a distance between the servers becomes excessively small, thus influencing heat dissipation; and moreover, as the bottom plate of the server is pressed against a lower server due to serious deformation of the bottom plate, which results in interference of the upper and the lower machine cases of the servers, and which further causes a problem in that the server cannot be easily pulled out from or pushed into the server cabinet.

### SUMMARY OF THE INVENTION

Accordingly, the present invention is directed to a machine case, which when an electronic device is loaded thereon, a bottom plate of the machine case becomes approximately flat.

The present invention is directed to a processing method of a machine case, so that a bottom plate of the machine case becomes approximately flat when an electronic device is loaded on the machine case.

The present invention provides a machine case for accommodating at least one electronic device. The machine case includes a top plate, a plurality of side plates, and a bottom plate. Every two adjacent side plates are connected to each other, and each side plate has a first side edge and a second side edge opposite to each other. The first side edge is connected to the top plate, and the second side edge is connected to the bottom plate. The bottom plate has a smooth arc surface, the smooth arc surface has a vertex, and a distance between the vertex of the smooth arc surface and the top plate is less than a distance between any other part of the smooth arc surface and the top plate.

The present invention further provides a processing method of a machine case, in which the machine case is used for accommodating at least one electronic device. The processing method of a machine case includes: calculating a deformation of a bottom plate of the machine case when at least one electronic device is accommodated in the machine case; fabricating a smooth arc surface on the bottom plate according to the deformation, in which the smooth arc surface has a vertex, and in which a distance between the vertex of the smooth arc surface and a top plate of the machine case is less than a distance between any other part of the smooth arc surface and the top plate of the machine case.

Based on the above, according to the machine case and the processing method thereof, a smooth arc surface protruding towards the top plate is formed on the bottom plate in advance, so that when an electronic device is placed on the bottom plate, the smooth arc surface deforms due to the gravity of the electronic device and becomes flat, thus avoiding interference with other machine cases.

In order to make the aforementioned and other objectives and advantages of the present invention comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic front view of conventional servers placed in a server cabinet.

FIG. 2A is a schematic front view of a machine case according to an embodiment of the present invention.

FIG. 2B to FIG. 2C are schematic front views of electronic devices accommodated in the machine case shown in FIG. 2A.

FIG. 3A is a schematic side view of a bottom plate of a machine case according to another embodiment of the present invention.

FIG. 3B is a schematic top view of the bottom plate of the machine case in FIG. 3A.

FIG. 4 is a schematic flow chart of a processing method of a machine case according to an embodiment of the present invention.

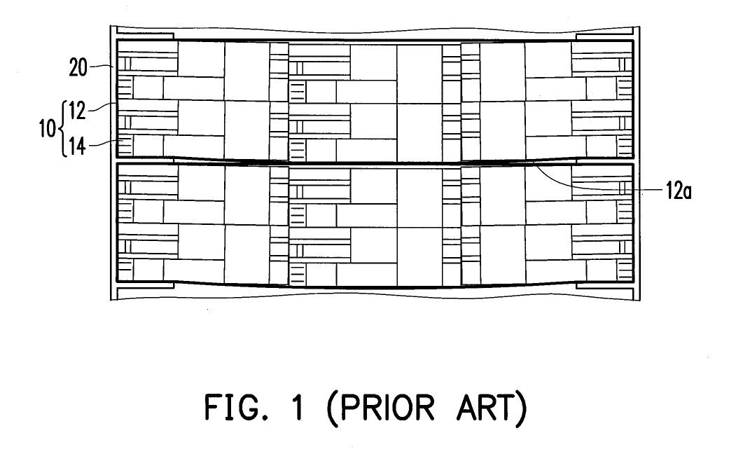

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

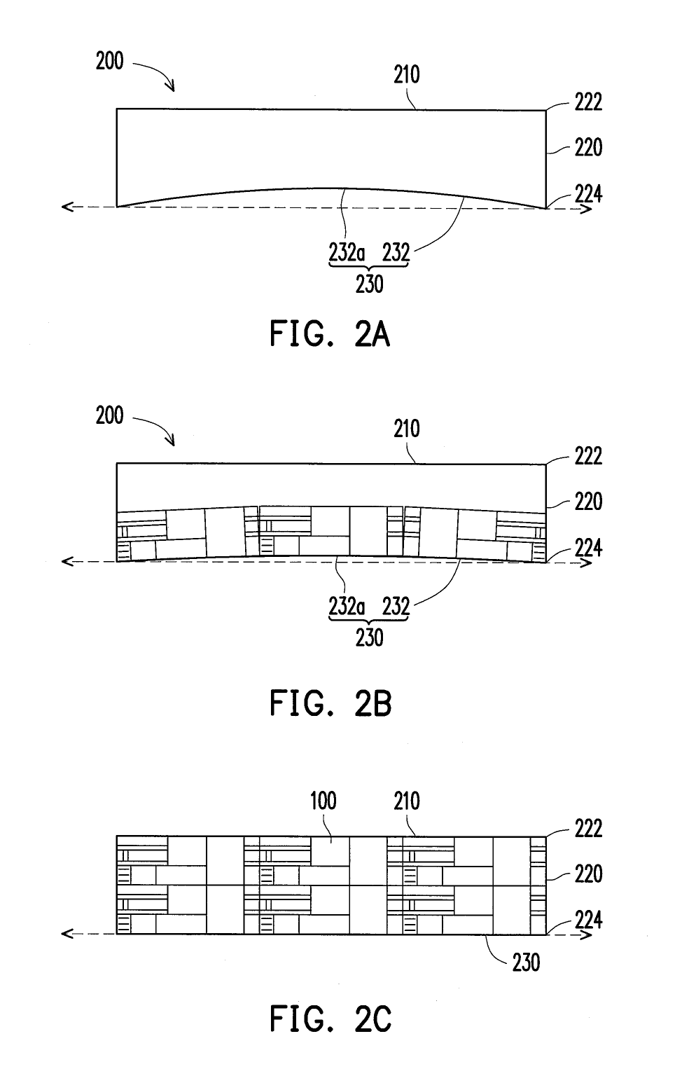

FIG. 2A is a schematic front view of a machine case according to an embodiment of the present invention. FIG. 2B to FIG. 2C are schematic front views of electronic devices accommodated in the machine case in FIG. 2A. Referring to FIG. 2A to FIG. 2C, the machine case 200 of this embodiment includes a top plate 210, a plurality of side plates 220, and a bottom plate 230. Every two adjacent side plates 220 are connected to each other, and each side plate 220 has a first side edge 222 and a second side edge 224 opposite to each other. The first side edge 222 is connected to the top plate 210, and the second side edge 224 is connected to the bottom plate 230. The bottom plate 230 has a smooth arc surface 232, in which the smooth arc surface 232 has a vertex 232a, and in which a distance between the vertex 232a of the smooth arc surface 232 and the top plate 210 is less than a distance between any other part of the smooth arc surface 232 and the top plate 210.

The machine case 200 of this embodiment is substantially a cuboid, but when the machine case 200 of this embodiment does not accommodate any electronic device 100 (as shown in FIG. 2A), as the bottom plate 230 has a smooth arc surface 232, the machine case 200 is not a generally known cuboid with completely flat surfaces. When three sets of electronic devices 100 are placed on the bottom plate 230 (as shown in FIG. 2B), the bottom plate 230 deforms due to the gravity of the electronic devices 100, and the curvature of the smooth arc surface 232 is decreased. Compared with the machine case 200 in FIG. 2A, the machine case 200 in FIG. 2B is more like a cuboid, so that the machine case 200 in FIG. 2B has enough space for placing the rest of the three sets of electronic devices 100. When all the electronic devices 100 are placed in the machine case 200 (as shown in FIG. 2C), the bottom plate 230 becomes approximately flat, so that the machine case 200 in FIG. 2C is more like a cuboid, compared with the machine case 200 in FIG. 2B. The machine case 200 may be configured to accommodate any number of the electronic devices 100. In one embodiment, for example, the machine case 200 may be configured to accommodate up to six sets of electronic devices 100, although alternative configurations which accommodate more or less than six sets of the electronic devices 100 are contemplated.

The smooth arc surface 232 protruding towards the top plate 210 is fabricated on the whole bottom plate 230 of the machine case 200 of this embodiment in advance, so that when the electronic device 100 is loaded on the bottom plate 230 and the bottom plate 230 deforms, the smooth arc surface 232 originally protruding towards the top plate 210 gradually becomes approximately flat. If the machine case 200 in FIG. 2C is placed on a bracket that merely supports a server cabinet of two sides of the bottom plate 230, an original distance between the machine case 200 of this embodiment and a lower machine case can be maintained, compared with a conventional machine case 12, thereby avoiding the problem of heat dissipation and interference.

In addition, the curvature of the smooth arc surface 232 and the position of the vertex 232a can be adjusted according to the weight distribution of the electronic device 100, so that after all the electronic devices 100 are placed in the machine case 200, the bottom plate 230 gradually deforms due to gravity and becomes approximately flat. In the embodiment of FIG. 2A to FIG. 2C, the whole bottom plate 230 is the range of the smooth arc surface 232. Additionally, in this embodiment, the top plate 210, the side plate 220, and the bottom plate 230 are formed integrally, and the electronic device 100 can be pushed in or pulled out from a side of the machine case 200. Definitely, the type of the machine case 200 is not limited herein.

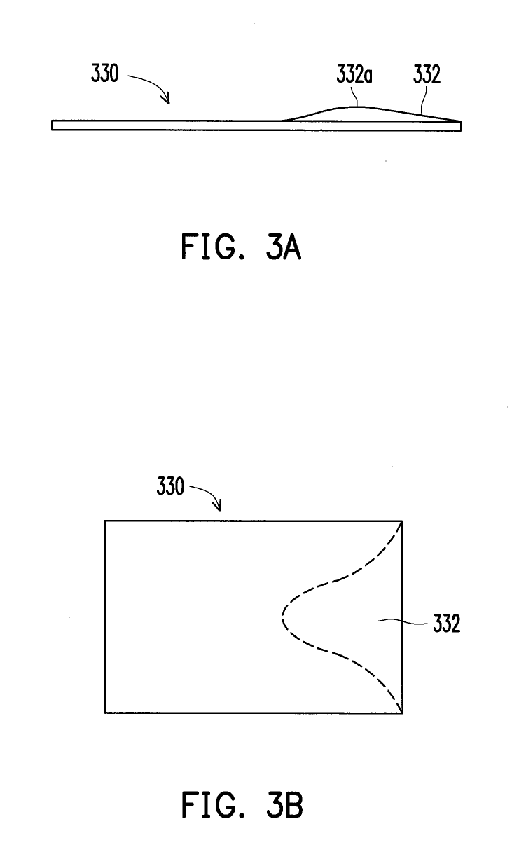

FIG. 3A is a schematic side view of a bottom plate of a machine case according to another embodiment of the present invention. FIG. 3B is a schematic top view of the bottom plate of the machine case shown in FIG. 3A. Referring to FIG. 3A and FIG. 3B, a difference between the embodiment in FIG. 3A and the embodiment shown in FIG. 2A is that a smooth arc surface 332 in FIG. 3A exists in only a part of a bottom plate 330, whereas the other parts of the bottom plate 330 are still flat. In FIG. 2A, the smooth arc surface 232 is located along the whole bottom plate 230.

The range, the position, and the curvature of the smooth arc surface 332 are dependent on the load condition of the electronic device 100. In a situation that the electronic device 100 is merely placed on a part of the bottom plate 330, or a heavier electronic device 100 is focused on a part of the bottom plate 330, the bottom plate 330 may deform only where the electronic device 100 is loaded. In this manner, the smooth arc surface 332 may be fabricated only at the part of the bottom plate 330 that deforms in advance, when the electronic device 100 is loaded. Therefore, before processing, the deformation of the bottom plate 330 after the electronic device 100 is placed on the bottom plate 330 is estimated in advance, and then the range, the position, and the curvature of the smooth arc surface 332 formed on the bottom plate 330 are determined according to the estimated deformation.

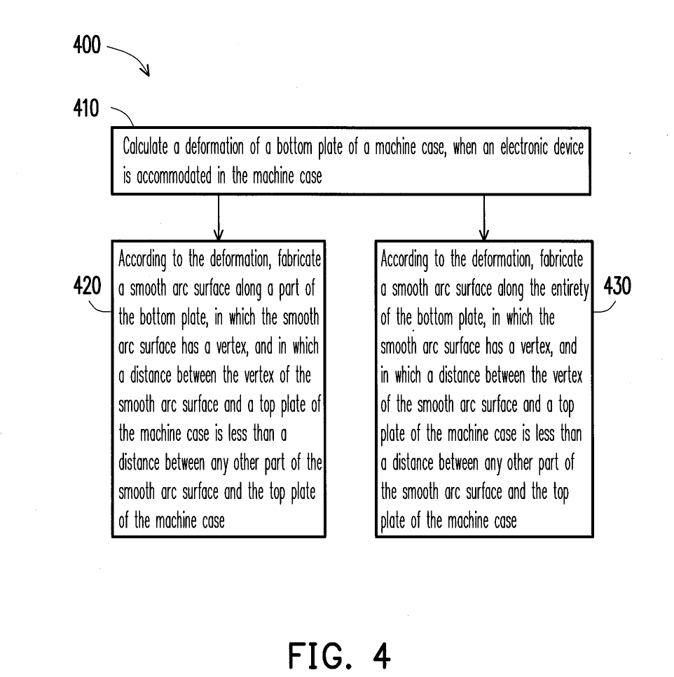

FIG. 4 is a schematic flow chart of a processing method 400 of fabricating a machine case according to an embodiment of the present invention. The machine case in which the processing method is applicable can accommodate at least one electronic device, and when an electronic device is loaded on a bottom plate of the machine case, the bottom plate is approximately flat. The processing method 400 of a machine case may include the following steps. First, a deformation of a bottom plate of a machine case is calculated when an electronic device is accommodated in the machine case (Step 410).

A fabricator can place an electronic device in the machine case for a period of time in the way of actual experiments, and after the deformation of the bottom plate is stable, the deformation of the bottom plate is calculated. Or, in the way of simulation, the weight distribution of the electronic device in the machine case is calculated, and parameters of the material and the size of the bottom plate are introduced in order to calculate the deformation of the bottom plate in theory when the electronic device is loaded.

Next, according to the deformation, a smooth arc surface is fabricated on the bottom plate, in which the smooth arc surface has a vertex, and in which a distance between the vertex of the smooth arc surface and a top plate of the machine case is less than a distance between any other part of the smooth arc surface and the top plate of the machine case. When the smooth arc surface is fabricated, the smooth arc surface is formed along only a part of the bottom plate (Step 420) or is formed along the entirety of the bottom plate (Step 430). If the deformation of the bottom plate after the electronic device is loaded merely exists along only a part of the bottom plate, Step 420 is directly performed after Step 410. If the deformation of the bottom plate after the electronic device is loaded exists along the entirety of the bottom plate, Step 430 is directly performed after Step 410.

In principle, the shape of the smooth arc surface is the same as the shape of deformation of the bottom plate when the electronic device is loaded on the bottom plate, but in a direction opposite to the deformation direction. When the electronic device is loaded on the bottom plate, the bottom plate deforms and protrudes in a direction away from the top plate, while the smooth arc surface protrudes towards the direction of the top plate, so that when the electronic device is placed on the bottom plate, the bottom plate changes from the smooth arc surface into a flat surface due to the gravity of the electronic device. In addition, in one embodiment, the smooth arc surface is fabricated in the manner of stamping, but the method for forming the smooth arc surface on the bottom plate is not limited thereto.

Through the above steps a smooth arc surface is formed on the bottom plate, thus completing the processing of the machine case. When the machine case loaded with the electronic device is placed in the server cabinet, brackets at two sides may be used to support the machine case. The bottom plate can also be flat, thus avoiding interference with a lower machine case.

In view of the above, according to the machine case and the processing method thereof according to the present invention, a smooth arc surface protruding towards the top plate is formed on the bottom plate in advance, so that when an electronic device is placed on the bottom plate, the smooth arc surface deforms due to the gravity of the electronic device and becomes flat. When the machine case loaded with the electronic device is placed in the server cabinet, a distance between the machine case and a lower machine case can be maintained, so that not only the space for heat dissipation can be maintained, but also interference between the upper and the lower machine cases is avoided, so that the problem of difficulty of pulling the machine case out from or pushing the machine case into the server cabinet is solved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A machine case, for accommodating at least one electronic device, comprising:
a top plate;
a plurality of side plates, wherein every two adjacent side plates are connected to each other, each side plate has a first side edge and a second side edge opposite to each other, and the first side edges are connected to the top plate; and
a bottom plate, connected to the second side edges, wherein the bottom plate has a smooth arc surface, the smooth arc surface has a vertex, and a distance between the vertex of the smooth arc surface and the top plate is less than a distance between any other part of the smooth arc surface and the top plate.

2. The machine case according to claim 1, wherein the smooth arc surface occupies a part of the bottom plate.

3. The machine case according to claim 1, wherein the smooth arc surface occupies an entirety of the bottom plate.

4. The machine case according to claim 1, wherein the top plate, the side plates, and the bottom plate are formed integrally.

5. A processing method of a machine case, wherein the machine case is used for accommodating at least one electronic device, and the processing method of the machine case comprises:
calculating a deformation of a bottom plate of the machine case when the at least one electronic device is placed on the machine case; and
fabricating a smooth arc surface according to the deformation, wherein the smooth arc surface has a vertex, and a distance between the vertex of the smooth arc surface and a top plate of the machine case is less than a distance between any other part of the smooth arc surface and the top plate of the machine case.

6. The processing method of a machine case according to claim 5, wherein said fabricating the smooth arc surface comprises forming the smooth arc surface on a part of the bottom plate.

7. The processing method of a machine case according to claim 5, wherein said fabricating the smooth arc surface comprises forming the smooth arc surface on all of the bottom plate.

8. The processing method of a machine case according to claim 5, wherein the smooth arc surface is fabricated in the manner of stamping.
